(19) United States
(12) Patent Application Publication
(10) Pub. No.: US 2025/0269438 A1
(43) Pub. Date: Aug. 28, 2025

(54) CHUCK ASSEMBLY, PLANARIZATION PROCESS, APPARATUS AND METHOD OF MANUFACTURING AN ARTICLE

(71) Applicant: CANON KABUSHIKI KAISHA, Tokyo (JP)

(72) Inventors: Seth J. Bamesberger, Austin, TX (US); Byung-Jin Choi, Austin, TX (US)

(21) Appl. No.: 18/589,272

(22) Filed: Feb. 27, 2024

(51) Int. Cl. B23B 31/117; B24B 37/30

(52) U.S. Cl. CPC B23B 31/1172; B24B 37/30

(57) ABSTRACT

A chuck assembly for holding a plate comprises a plate holding member configured to hold the plate, the plate holding member including a central opening, a rigid member configured to hold the plate holding member, a first channel formed by the plate holding member, a second channel formed by the rigid member, a first fluid conduit in communication with the second channel, and, a second fluid conduit at least partially disposed within the second channel and in communication with the first channel.

### BACKGROUND

### Field of Art

The present disclosure relates to substrate processing, and more particularly, to a chuck assembly used in the planarization of surfaces in semiconductor fabrication.

### Description of the Related Art

Planarization techniques are useful in fabricating semiconductor devices. For example, the process for creating a semiconductor device includes repeatedly adding and removing material to and from a substrate. This process can produce a layered substrate with an irregular height variation (i.e., topography), and as more layers are added, the substrate height variation can increase. The height variation has a negative impact on the ability to add further layers to the layered substrate. Separately, semiconductor substrates (e.g., silicon wafers) themselves are not always perfectly flat and may include an initial surface height variation (i.e., topography). One method of addressing this issue is to planarize the substrate between layering steps. Various lithographic patterning methods benefit from patterning on a planar surface. In ArFi laser-based lithography, planarization reduces the impact of depth of focus (DOF) limitations, and improves critical dimension (CD), and critical dimension uniformity. In extreme ultraviolet lithography (EUV), planarization improves feature placement and reduces the impact of DOF limitations. In nanoimprint lithography (NIL) planarization improves feature filling and CD control after pattern transfer.

A planarization technique sometimes referred to as inkjet-based adaptive planarization (IAP) involves dispensing a variable drop pattern of polymerizable material between the substrate and a superstrate, where the drop pattern varies depending on the substrate topography. A superstrate is then brought into contact with the polymerizable material after which the material is polymerized on the substrate, and the superstrate removed. Improvements in planarization techniques, including IAP techniques, are desired for improving, e.g., whole wafer processing and semiconductor device fabrication.

In current planarization methods, there may be difficulty in controlling the superstrate curvature and spread of polymerizable material near the edge of the superstrate. Furthermore, there may be difficulty in separating the superstrate from a cured film, in particular when the superstrate has a similar size to the substrate. There is a need in the art for a chuck assembly and planarization method with improved control of the superstrate curvature and improved separation from the cured film. More particularly, there is a need in the art for a chuck assembly that has improved control of the superstrate curvature at the time of spreading of formable material while also having the ability to provide consistent separation front propagation at the time of separating the superstrate from the cured material.

### SUMMARY

A chuck assembly for holding a plate comprises a plate holding member configured to hold the plate, the plate holding member including a central opening, a rigid member configured to hold the plate holding member, a first channel formed by the plate holding member, a second channel formed by the rigid member, a first fluid conduit in communication with the second channel; and, a second fluid conduit at least partially disposed within the second channel and in communication with the first channel.

A planarization system comprises a chuck assembly for holding a plate, the chuck assembly comprising, a plate holding member configured to hold the plate, the plate holding member including a central opening, a rigid member configured to hold the plate holding member, a first channel formed by the plate holding member, a second channel formed by the rigid member, a first fluid conduit in communication with the second channel, and a second fluid conduit at least partially disposed within the second channel and in communication with the first channel, a substrate chuck configured to hold a substrate, a fluid dispenser configured to dispense formable material on the substrate, a positioning system configured to contact the formable material with the plate, and a curing system configured to cure the formable material under the plate so as to form cured formable material on the substrate.

A method of manufacturing an article comprises dispensing a formable material on a substrate, retaining a plate with a plate chuck assembly, the plate chuck assembly comprising: a plate holding member configured to hold the plate, the plate holding member including a central opening, a rigid member configured to hold the plate holding member, a first channel formed by the plate holding member, a second channel formed by the rigid member, a first fluid conduit in communication with the second channel, and a second fluid conduit at least partially disposed within the second channel and in communication with the first channel, contacting the plate with the formable material dispensed on the substrate, curing the formable material with a curing source, separating the plate from the cured formable material, and processing the cured formable material to make the article.

These and other objects, features, and advantages of the present disclosure will become apparent upon reading the following detailed description of exemplary embodiments of the present disclosure, when taken in conjunction with the appended drawings, and provided claims.

### BRIEF DESCRIPTION OF DRAWINGS

So that features and advantages of the present disclosure can be understood in detail, a more particular description of embodiments of the disclosure may be had by reference to the embodiments illustrated in the appended drawings. It is to be noted, however, that the appended drawings only illustrate typical embodiments of the disclosure and are therefore not to be considered limiting of its scope, for the disclosure may admit to other equally effective embodiments.

FIG. 1 is a schematic diagram illustrating an example planarization system in accordance with an aspect of the present disclosure.

FIGS. 2A to 2C illustrate a schematic cross section of an example planarization process in accordance with an aspect of the present disclosure.

FIG. 3A is a bottom view of an example chuck assembly in accordance with an aspect of the present disclosure.

FIG. 3B is a top view of the example chuck assembly of FIG. 3A.

FIG. 4A is a cross-section view of the example chuck assembly taken along line 4A-4A of FIG. 3B.

FIG. 4B is an enlarged view of portion 4B of FIG. 4A.

FIG. 4C is a perspective view of portion 4B of FIG. 4A.

FIG. 4D is an enlarged schematic view of portion 4D of FIG. 4B.

FIG. 5A is cross-section view of the example chuck assembly taken along lone 5A-5A of FIG. 3A.

FIG. 5B is an enlarged view of portion 5B of FIG. 5A.

FIG. 5C is a perspective view of portion 5B of FIG. 5A.

FIG. 5D is an exploded perspective view of the example chuck assembly.

FIG. 6A is a cross-section view of the example chuck assembly taken along line 6A-6A of FIG. 3B.

FIG. 6B is an enlarged view of portion 6B of FIG. 6A.

FIG. 6C is perspective view of the portion 6B of FIG. 6A.

FIG. 7 is an exploded bottom view of the example chuck assembly.

FIG. 8A is an enlarged view of portion 8A of FIG. 4A.

FIG. 8B is a perspective view of portion 8A of FIG. 4A.

FIG. 9 shows a flow chart of an example planarization method in accordance with aspect of the present disclosure.

FIGS. 10A to 10N show a series of schematic cross sections of the planarization method of FIG. 9.

While the subject disclosure will now be described in detail with reference to the figures, it is done so in connection with the illustrative exemplary embodiments. It is intended that changes and modifications can be made to the described exemplary embodiments without departing from the true scope and spirit of the subject disclosure as defined by the appended claims.

### DETAILED DESCRIPTION

### Planarization System

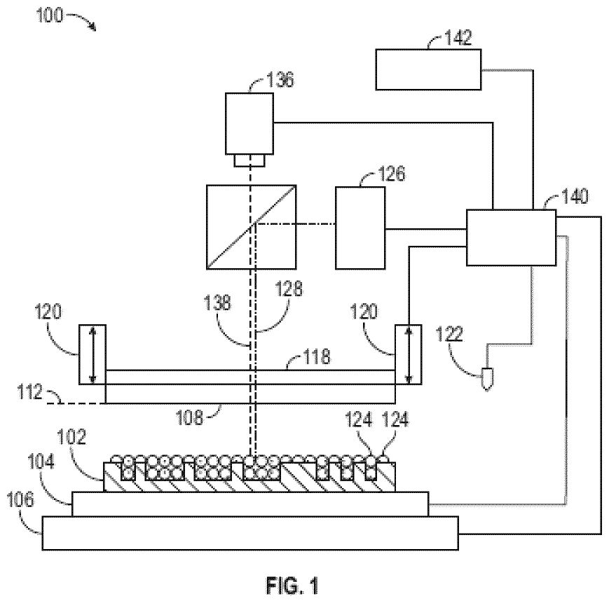

FIG. 1 illustrates an example system for planarization in accordance with an aspect of the present disclosure. The planarization system 100 is used to planarize a film on a substrate 102. The substrate 102 may be coupled to a substrate chuck 104. The substrate chuck 104 may be but is not limited to a vacuum chuck, pin-type chuck, groove-type chuck, electrostatic chuck, electromagnetic chuck, and/or the like.

The substrate 102 and the substrate chuck 104 may be further supported by a substrate positioning stage 106. The substrate positioning stage 106 may provide translational and/or rotational motion along one or more of the x-, y-, z-, θ-, ψ, and φ-axes. The substrate positioning stage 106, the substrate 102, and the substrate chuck 104 may also be positioned on a base (not shown). The substrate positioning stage may be a part of a positioning system.

Spaced apart from the substrate 102 is a superstrate 108 (also referred herein as a plate) having a working surface 112 facing substrate 102. The superstrate 108 may be formed from materials including, but not limited to, fused silica, quartz, silicon, organic polymers, siloxane polymers, borosilicate glass, fluorocarbon polymers, metal, hardened sapphire, ceramic, glass, and/or the like. In an embodiment the superstrate is readily transparent to UV light. The working surface 112 is generally of the same areal size or slightly smaller than the surface of the substrate 102.

The superstrate 108 may be coupled to or retained by a superstrate chuck assembly 118, which is discussed in more detail below. The superstrate chuck assembly 118 may be coupled to a planarization head 120 which is a part of the positioning system. The planarization head 120 may be movably coupled to a bridge. The planarization head 120 may include one or more actuators such as voice coil motors, piezoelectric motors, linear motor, nut and screw motor, etc., which are configured to move the superstrate chuck assembly 118 relative to the substrate 102 in at least the z-axis direction, and potentially other directions (e.g. x-, y-, θ-, ψ-, and φ-axis).

The planarization system 100 may further comprise a fluid dispenser 122. The fluid dispenser 122 may also be movably coupled to the bridge. In an embodiment, the fluid dispenser 122 and the planarization head 120 share one or more of all positioning components. In an alternative embodiment, the fluid dispenser 122 and the planarization head move independently from each other. The fluid dispenser 122 may be used to deposit droplets of liquid formable material 124 (e.g., a photocurable polymerizable material) onto the substrate 102 with the volume of deposited material varying over the area of the substrate 102 based on at least in part upon its topography profile. Different fluid dispensers 122 may use different technologies to dispense formable material 124. When the formable material 124 is jettable, ink jet type dispensers may be used to dispense the formable material. For example, thermal ink jetting, microelectromechanical systems (MEMS) based ink jetting, valve jet, and piezoelectric ink jetting are common techniques for dispensing jettable liquids.

The planarization system 100 may further comprise a curing system that includes a radiation source 126 that directs actinic energy, for example, UV radiation, along an exposure path 128. The planarization head 120 and the substrate positioning stage 106 may be configured to position the superstrate 108 and the substrate 102 in superimposition with the exposure path 128. The radiation source 126 sends the actinic energy along the exposure path 128 after the superstrate 108 has contacted the formable material 124. FIG. 1 shows the exposure path 128 when the superstrate 108 is not in contact with the formable material 124. This is done for illustrative purposes so that the relative position of the individual components can be easily identified. An individual skilled in the art would understand that exposure path 128 would not substantially change when the superstrate 108 is brought into contact with the formable material 124.

The planarization system 100 may further comprise a camera 136 positioned to view the spread of formable material 124 as the superstrate 108 contacts the formable material 124 during the planarization process. FIG. 1 illustrates an optical axis 138 of the field camera's imaging field. As illustrated in FIG. 1, the planarization system 100 may include one or more optical components (dichroic mirrors, beam combiners, prisms, lenses, mirrors, etc.) which combine the actinic radiation with light to be detected by the camera 136. The camera 136 may include one or more of a CCD, a sensor array, a line camera, and a photodetector which are configured to gather light at a wavelength that shows a contrast between regions underneath the superstrate 108 and in contact with the formable material 124 and regions underneath the superstrate 108 but not in contact with the formable material 124. The camera 136 may be configured to provide images of the spread of formable material 124 underneath the superstrate 108, and/or the separation of the superstrate 108 from cured formable material 124. The camera 136 may also be configured to measure interference fringes, which change as the formable material 124 spreads between the gap between the working surface 112 and the substrate surface and as the distance between the working surface 112 and the substrate surface changes.

The planarization system 100 may be regulated, controlled, and/or directed by one or more processors 140 (controller) in communication with one or more components and/or subsystems such as the substrate chuck 104, the substrate positioning stage 106, the superstrate chuck assembly 118, the planarization head 120, the fluid dispenser 122, the radiation source 126, and/or the camera 136. The processor 140 may operate based on instructions in a computer readable program stored in a non-transitory computer memory 142. The processor 140 may be or include one or more of a CPU, MPU, GPU, ASIC, FPGA, DSP, and a general-purpose computer. The processor 140 may be a purpose-built controller or may be a general-purpose computing device that is adapted to be a controller. Examples of a non-transitory computer readable memory include but are not limited to RAM, ROM, CD, DVD, Blu-Ray, hard drive, networked attached storage (NAS), an intranet connected non-transitory computer readable storage device, and an internet connected non-transitory computer readable storage device. All of the method steps described herein may be executed by the processor 140.

In operation, either the planarization head 120, the substrate position stage 106, or both vary a distance between the superstrate 108 and the substrate 102 to define a desired space (a bounded physical extent in three dimensions) that is filled with the formable material 124. For example, the planarization head 120 may be moved toward the substrate and apply a force to the superstrate 108 such that the superstrate contacts and spreads droplets of the formable material 124 as further detailed herein.

### Planarization Process

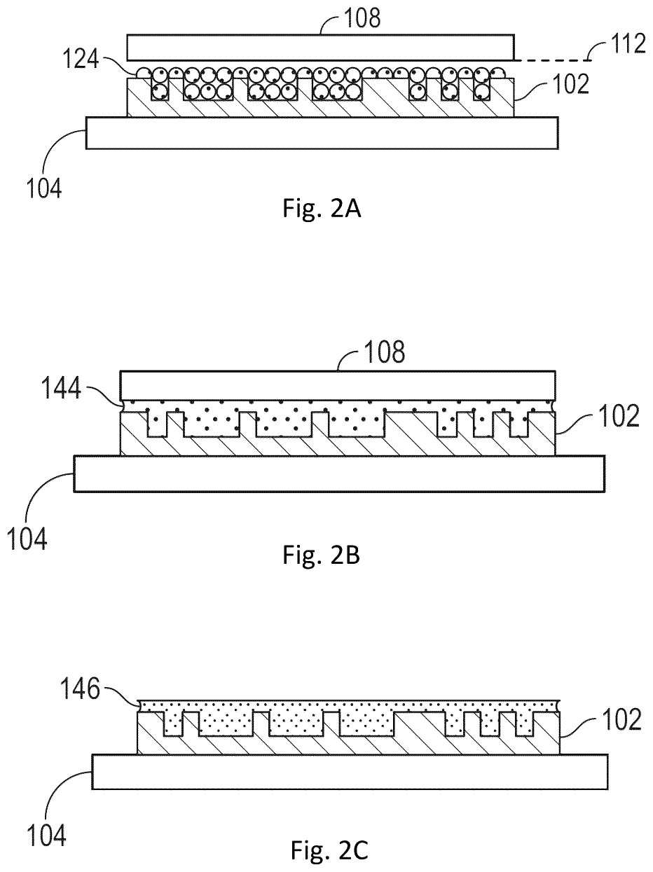

The planarization process includes steps which are shown schematically in FIGS. 2A-2C. As illustrated in FIG. 2A, the formable material 124 is dispensed in the form of droplets onto the substrate 102. As discussed previously, the substrate surface has some topography which may be known based on previous processing operations or may be measured using a profilometer, AFM, SEM, or an optical surface profiler based on optical interference effect like Zygo NewView 8200. The local volume density of the deposited formable material 124 is varied depending on the substrate topography. The superstrate 108 is then positioned in contact with the formable material 124.

FIG. 2B illustrates a post-contact step after the superstrate 108 has been brought into full contact with the formable material 124 but before a polymerization process starts. As the superstrate 108 contacts the formable material 124, the droplets merge to form a formable material film 144 that fills the space between the superstrate 108 and the substrate 102. Preferably, the filling process happens in a uniform manner without any air or gas bubbles being trapped between the superstrate 108 and the substrate 102 in order to minimize non-fill defects. The polymerization process or curing of the formable material 124 may be initiated with actinic radiation (e.g., UV radiation). For example, radiation source 126 of FIG. 1 can provide the actinic radiation causing formable material film 144 to cure, solidify, and/or cross-link, defining a cured planarized layer 146 on the substrate 102. Alternatively, curing of the formable material film 144 can also be initiated by using heat, pressure, chemical reaction, other types of radiation, or any combination of these. Once cured, planarized layer 146 is formed, the superstrate 108 can be separated therefrom. FIG. 2c illustrates the cured planarized layer 146 on the substrate 102 after separation of the superstrate 108. The substrate and the cured layer may then be subjected to additional known steps and processes for device (article) fabrication, including, for example, patterning, curing, oxidation, layer formation, deposition, doping, planarization, etching, formable material removal, dicing, bonding, and packaging, and the like. The substrate may be processed to produce a plurality of articles (devices).

### Spreading, Filling, and Curing Planarization Material Between Superstrate and Substrate

One scheme for minimizing entrapment of air or gas bubbles between the superstrate 108 and the substrate 102 as the formable material 124 droplets spread, merge and fill the gap between the superstrate 108 and the substrate 102 is to position the superstrate 108 such that it makes initial contact with the formable material 124 in the center of the substrate 102 with further contact then proceeding radially in a center to perimeter fashion. This requires a deflection or bowing of the superstrate 108 or substrate 102 or both to create a curvature in the superstrate 108 relative to the substrate 102. The curvature of the superstrate 108 facilitates the expulsion of the air or gas bubbles as the formable material 124 spreads. Such a superstrate 108 profile can be obtained by, for example, applying a back pressure to the interior region of the superstrate. However, in doing so, a perimeter holding region is still required to keep the superstrate 108 retained on the superstrate chuck assembly 118. Given that the superstrate 108 is typically of the same or similar areal dimension as the substrate 102, if both the perimeter edges of the superstrate 108 and the substrate are 102 chucked flat during formable material 124 droplet spreading and merging, there will be no available superstrate curvature profile in this flat chucked area. This may compromise the droplet spreading and merging, which may also lead to non-fill defects in the region. To minimize non-fill defects, the superstrate curvature needs to be controlled over the full superstrate diameter during the fluid spreading process. In addition, once spreading and filling of the formable material is complete, the resultant stack of a superstrate chuck, a chucked superstrate, the formable material, substrate, and a substrate chuck can be an over-constrained system. This may cause a non-uniform planarization profile of the resultant planarized film layer. That is, in such an over-constrained system, all flatness errors or variations from the superstrate chuck, including front-back surface flatness, can be transmitted to the superstrate and impact the uniformity of the planarized film layer. Additionally, at the time of separating the superstrate from the cured film, it is desirable to achieve a consistent circumferential separation front between the superstrate and the cured film.

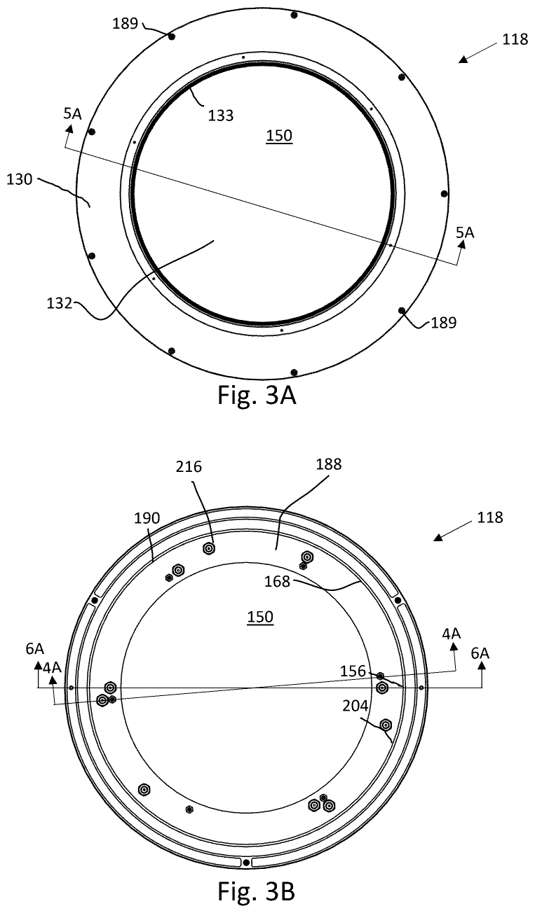

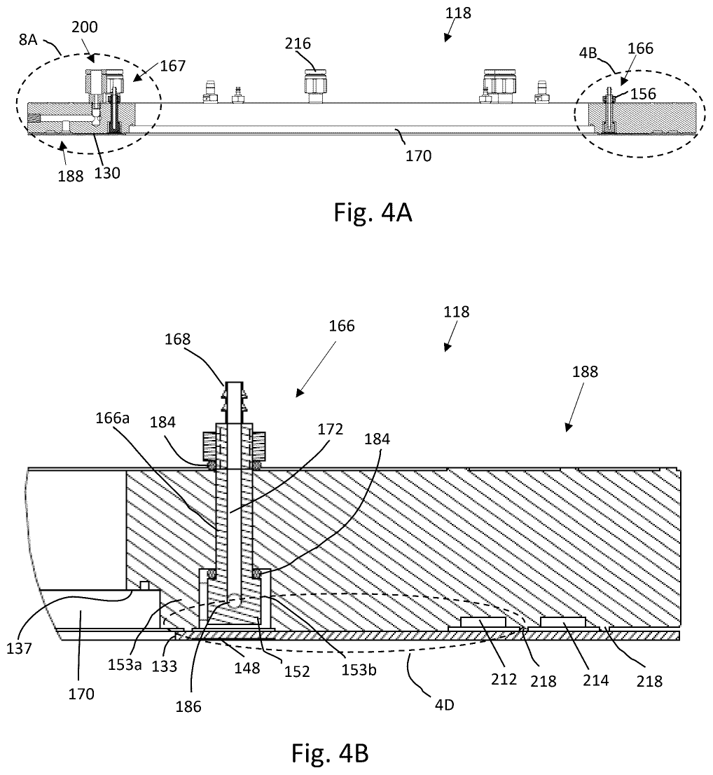

To resolve the above issues, a superstrate chuck assembly 118 is provided as shown in FIGS. 3A to 8B that provides both 1) improved spreading of formable material at the time of contacting the superstrate with the formable material and 2) improved separation front propagation at the time of separating the superstrate from the cured material.

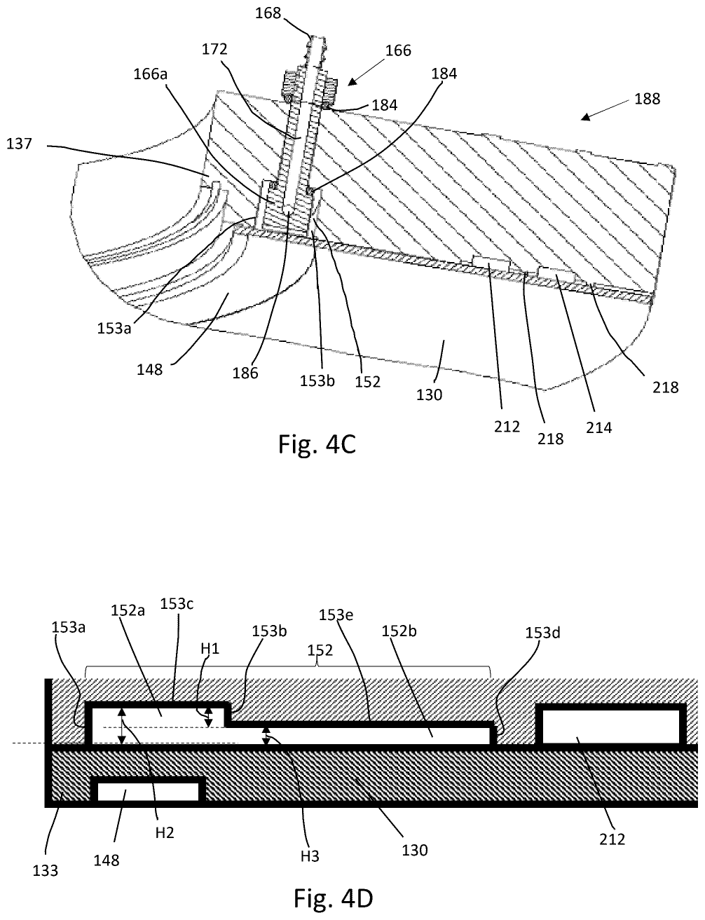

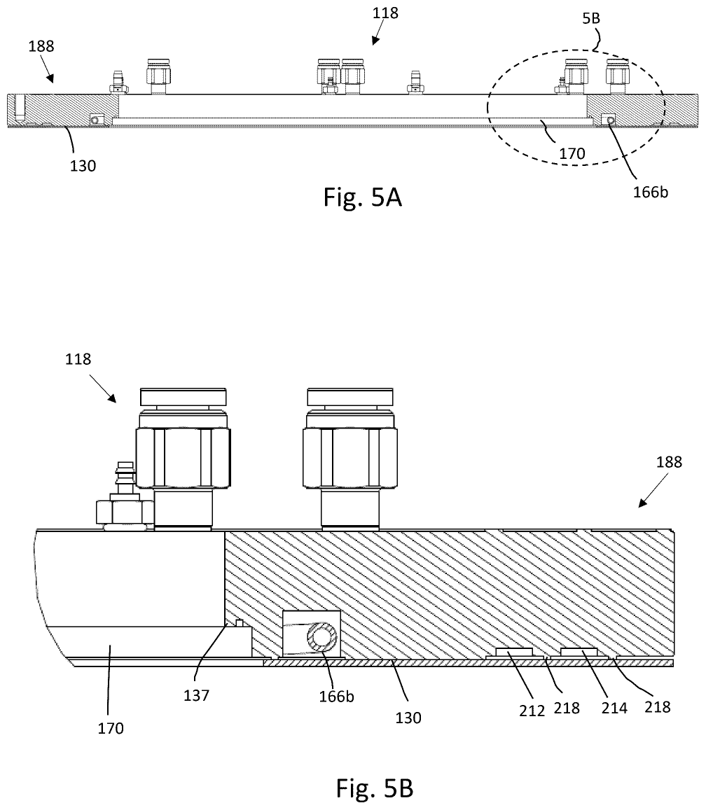

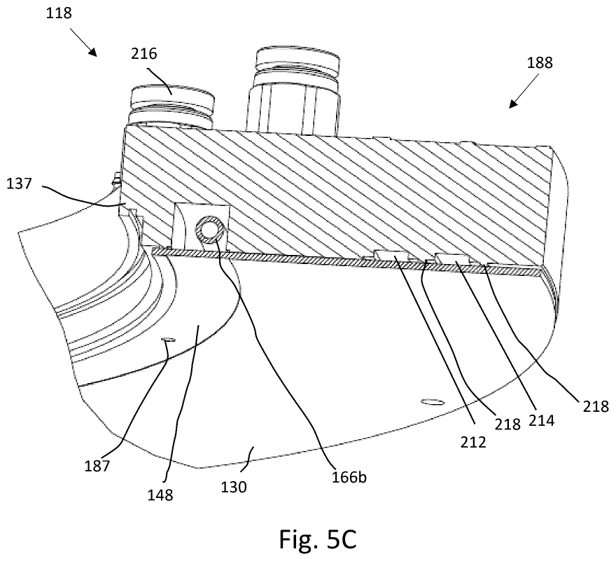

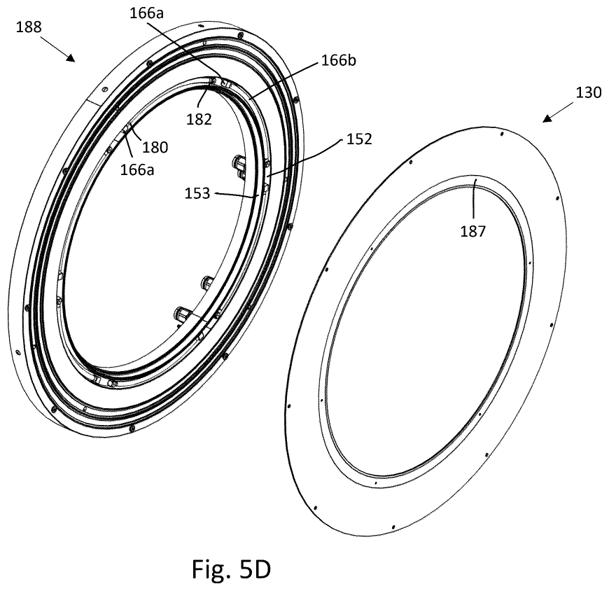

FIG. 3A shows a bottom view of the superstrate chuck assembly 118. FIG. 3B shows a top view of the superstrate chuck assembly 118. FIG. 4A shows a cross section taken along line 4A-4A of FIG. 3B. FIG. 4B shows an enlarged portion 4B of FIG. 4A. FIG. 4C shows a perspective view of the enlarged portion 4B of the FIG. 4A. FIG. 4D shows an enlarged schematic of portion 4D of FIG. 4B.

The superstrate chuck assembly 118 generally includes a rigid member 188 which may also be referred to as a support ring, a plate holding member 130 coupled with the rigid member 188, which is also referred herein as a member, and a light-transmitting member 150.

The rigid member 188 preferably has a ring shape with a central opening. The rigid member 188 may be composed of an opaque material with respect to UV light or may be composed of a material that is transparent to UV light. The rigid member 188 may be composed of plastic (e.g. acrylic), glass (e.g. fused silica, borosilicate), metal (e.g. aluminum, stainless steel), or ceramic (e.g. zirconia, sapphire, alumina).

The plate holding member 130 similarly preferably has a ring shape with a central opening 132. The plate holding member 130 may be made of a transparent material that allows UV light to pass through or may not be made of a transparent material that allows for UV light to pass through. That is the plate holding member 130 may or may not be composed of an opaque material with respect to UV light. The plate holding member 130 may be composed of a polymer (e.g., acrylic, fluoroelastomer), a glass (e.g. fused silica, borosilicate), metal (e.g. aluminum, stainless steel), or a ceramic (e.g. zirconia, sapphire, alumina). The plate holding member 130 may be configured so that the plate holding member 130 is generally flexible. However, as discussed in more detail below, portions of the plate holding member 130 can become effectively rigid when held against the rigid member 188 using a vacuum. The portion of the plate holding member 130 not held against the rigid member 188 may be considered a flexible portion. The flexible portion of the plate holding member 130 may be varied, as discussed below. However, while the portion of the plate holding member 130 that is actively flexible and actively rigid can vary, the composition of the plate holding member 130 is uniform, i.e., the same throughout. The plate holding member 130 may have a uniform thickness of 0.2 to 5 mm or 0.3 to 2 mm in an example embodiment. That is, all portions of the plate holding member 130, whether effectively flexible or effectively rigid, may have the same thickness. A thicker material with a low elastic modulus will be similarly flexible as a thin material with high elastic modulus. The plate holding member 130 may be composed of a material having modulus of elasticity (Young's modulus) of 0.1 to 210 GPa, 50 to 150 GPa, or 60 to 100 GPa. In one example embodiment, the modulus of elasticity may be 70 GPa.

The plate holding member 130 may further have a flexural rigidity of 0.01 to 5 Pa·m³, 0.1 to 4 Pa·m³, 0.5 to 3 Pa·m³, 1.0 to 2 Pa·m³. Additionally, a ratio of the flexural rigidity of the plate holding member to the flexural rigidity of the superstrate may be 0.01:1 to 5:1, 0.05:1 to 4:1, 0.1:1 to 3:1, or 0.5:1 to 1:1, preferably less than 1:1. Equation (1) below defines the flexural rigidity D in which: H is the thickness of the superstrate 108 or the plate holding member 130; v is Poisson's ratio of the material of the superstrate 108 or the plate holding member 130; and E is Young's modulus of the material of the superstrate 108 the plate holding member 130. For example, the flexural rigidity for the superstrate may be 2.12 while the flexural rigidity of the plate holding member 130 may be 0.29, 0.68, 0.82, or 2.30 Pa·m³. And the ratio of the flexural rigidity of the plate holding member 130 to the flexural rigidity of the superstrate 108 may be: 0.14:1; 0.32:1; 0.39:1; or 1.09:1.

$$D = \frac{{EH}^{3}}{12 ( 1 - {v}^{2} )} \qquad ( 1 )$$

The plate holding member 130 includes a first channel 148 (FIGS. 4B, 4C, 4D, 5B, 5C, 6B, 6C) configured to hold a portion of the superstrate 108 to the underside of the plate holding member 130. The first channel 148 may be an annular channel concentrically surrounding the central opening 132. The first channel 148 may be located adjacent the inner edge 133 of the plate holding member 130. The first channel 148 may be formed as a recessed portion within the thickness of plate holding member 130. The inner edge 133 of the member is also a sidewall of the plate holding member 130 that extends from an underside surface of the plate holding member 130.

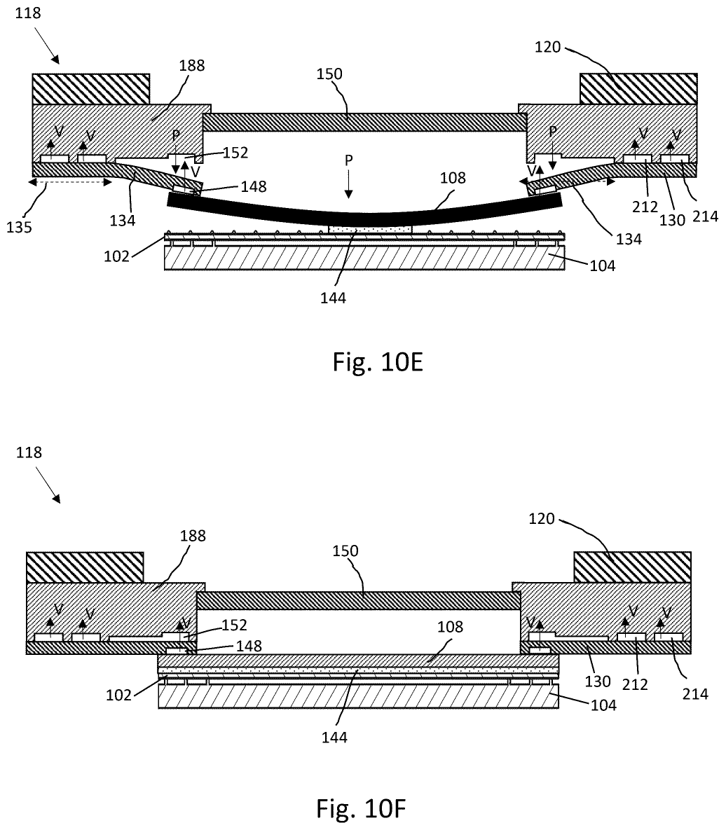

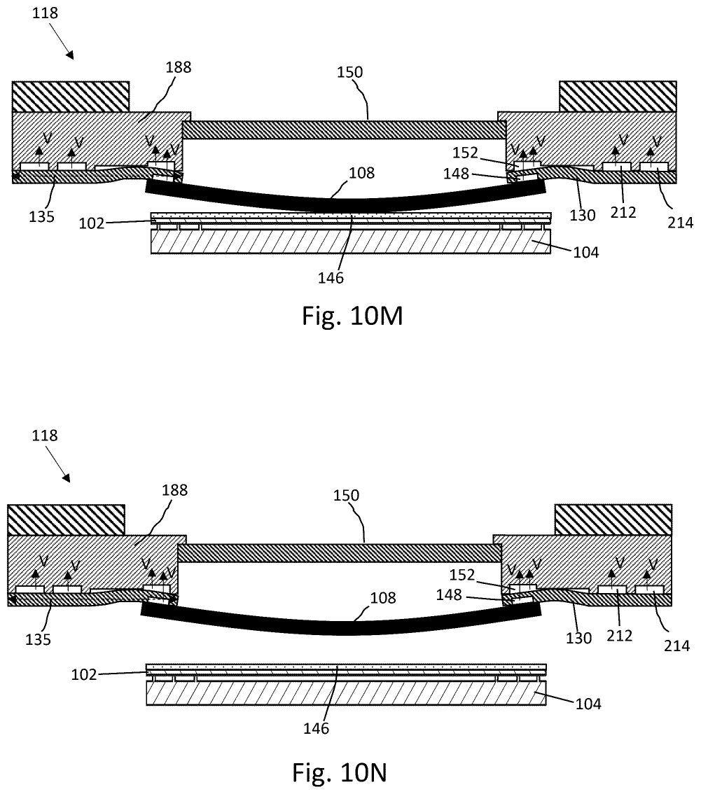

The light-transmitting member 150 covers the central opening 132 of the plate holding member 130. In one example embodiment, the light-transmitting member 150 is preferably transparent to UV light with high UV light transmissivity. That is, the material composition of the light-transmitting member 150 may be selected such that UV light used to cure the formable material passes through the light-transmitting member 150. In one example embodiment when the light-transmitting member 150 transmits UV light, the light-transmitting member may be composed of a material that transmits greater than 80% of light having a wavelength of 310-700 nm (i.e., UV light and visible light), e.g., sapphire, fused silica). In another example embodiment, the light-transmitting member need not be transparent with respect to UV light. When the light-transmitting member need not be transparent with respect to UV light, the light-transmitting member may be composed of a material that transmits greater than 80% of light having a wavelength of 400-700 nm (i.e., visible light), e.g., glass, borosilicate. That is, in the case when it is not necessary to transmit UV light, the light-transmitting member 150 should still transmit visible light. The light-transmitting member 150 is omitted from FIGS. 4A to 6C, 8A, and 8B for clarity, but is shown in FIGS. 3A, 3B, and 7, and schematically shown in FIGS. 10A to 10N. In the illustrated example embodiment, the light-transmitting member, if shown, would rest against the innermost step 137 of the rigid member 188. The light-transmitting member 150 may be one of: a Magnesium Fluoride (MgF₂) Window; Lithium Fluoride (LIF) Window; a Barium Fluoride (BaF₂); a Calcium Fluoride (CaF₂) Window; a Fused Silica Window; a Polycrystalline CVD Diamond Window, a Sodium Chloride (NaCl) Window; a Potassium Bromide (Br) Window; a Sapphire Window; a Zinc Sulfide (ZnS Window); a Zinc Selenide (ZnSe) Window; a Red Thallium Bromo-Iodide (TIBrₓI₁₋ₓ) Window; a Gallium Arsenide (GaAs) Window; a Cadmium Telluride (CdTe) Window; a Silicon (Si) Window; a Diamond-Like Carbon (DLC) Coated Silicon Window; a Germanium (Ge) Window; a BK7 Window; a plastic window; a metal window; a ceramic window; or a glass window. The light transmitting member 150 may have one or more coatings such as anti-reflection coating or a protective coating. In an alternative embodiment, the light transmitting member 150 may be optimized to transmit infrared light.

As best seen in FIGS. 4B, 4C and 4D the superstrate chuck assembly 118 may include a second channel 152 defined by the rigid member 188. More particularly, the second channel 152 includes a first area 152a and a second area 152b, where the first area 152a and the second area 152b are continuous. Because FIGS. 4B and 4C are to scale, the second area 152b is not perceivable in FIGS. 4B and 4C. FIG. 4D, however, shows a schematic view of the portion 4D in FIG. 4B, where the sizes of the first area 152a and the second area 152b are exaggerated so that the second area 152b is more clearly visible. As seen in FIG. 4D, the first area 152a is defined by two opposing concentric interior sidewalls 153a, 153b of the rigid member 188. The first sidewall 153a (i.e., the sidewall that is more radially inward) extends farther down relative to the first surface 153c of the first area 152a than the second sidewall 153b (i.e., the sidewall that is more radially outward). The second area 152b is defined by an edge of the second sidewall 153b intersecting with a second surface 153e, a third sidewall 153d, and the second surface 153e. The third sidewall 153d is located more radially outward than the second sidewall 153b. The second surface 153e extends radially from the second sidewall 153b to the third sidewall 153d. The third sidewall 153d extends down and terminates at the same relative height as the first sidewall 153a. The second area 152b has the same height as the third sidewall 153d.

The height H1 is the distance in the vertical direction from the first surface 153c serving as a reference point to the bottom of the second sidewall 153b (i.e., the distance from the first surface 153c to the second surface 153e). The height H2 is the distance in the vertical direction from the first surface 153c to the bottom of the first sidewall 153a, which is also the distance from the first surface 153c to the bottom of the third sidewall 153d. As seen in FIG. 4D, the height H2 is greater than the height H1. The height H2 may be 6.5 mm and the distance H1 may be 6.4 mm. The heights of H1 and H2 may be between 2 to 20 mm. The height H3 is the distance in the vertical direction from the second surface 153e to the bottom of the third sidewall 153d. The height H3 is selected based upon the material and mechanical properties of the superstrate and the mechanical material properties of the flexible portion 134. The height H3 may be selected based on finite element simulations of the superstrate and the flexible portion during separation. If the height H3 is too large, then the flexible portion will bend too much and the first channel will not be able to maintain vacuum with the superstrate, causing the superstrate to detach from the flex chuck and possibly be damaged. If the height H3 is too small, then the separation front will not propagate around the circumference of the substrate. In an example embodiment, the height H3 may be 5 μm to 100 μm. Thus, in an example embodiment, the first sidewall 153a may extend 5 to 100 μm beyond the second sidewall 153b. H2 is equal to H1 plus H3. Thus, as seen in FIG. 4D, the difference in distance between H1, H2, and H3 creates a step from the first area 152a to the second area 152b. This step structure provides a benefit in the step of separating the superstrate from a cured layer, which is described below. As also seen in FIG. 4D, the second channel 152, in a state when it is enclosed, may also be considered to be defined in part by an upper surface of the plate holding member 130. Furthermore, the first sidewall 153a forms an innermost rigid member land of the rigid member 188 that overlaps with an innermost plate holding member land formed from the inner edge/sidewall 133 of the plate holding member 130.

The superstrate chuck assembly 118 furthers include a first fluid conduit 154 in communication with the second channel 152 for pressurizing the second channel 152 and a cavity 170 described below. The superstrate chuck assembly 118 includes a second fluid conduit 166 in communication with the first channel 148 so that the superstrate can be held by the plate holding member 130 by reducing pressure in the first channel 148. One manner of reducing pressure in the first channel 148 is by providing a vacuum via second fluid conduit 166 and the channel 148. The second conduit 166 may include a fitting 166a and a tube 166b. The second conduit 166 is best shown in FIGS. 4B and 4C. The second conduit 166 includes a first plate holding vacuum passage 172 within the fitting 166a that ends with a fitting through hole 186. The fitting through hole 186 is located within the bottom portion of the fitting 166a. As best seen in FIG. 4B the bottom of the fitting 166a does not extend beyond the confines of the second channel 152, and more particularly, within the confines of the first area 152a. In an embodiment, the bottom of the fitting 166a does not extend beyond the second surface 153e. In other words, the fitting 166a does not extend beyond the first sidewall 153a of the rigid member 188. This is the case no matter the state of use of the plate holding member 130. That is, the fitting 166a does not move relative to the rigid member 188 regardless of whether the plate holding member 130 is fully retracted or fully extended. The different states of the plate holding member 130 are discussed below in more detail. The fitting 166a may be sealed within the rigid member 188 via sealing members 184. The sealing members may be gaskets or O-rings that prevent the air leakage when changing the pressure in the second channel 152.

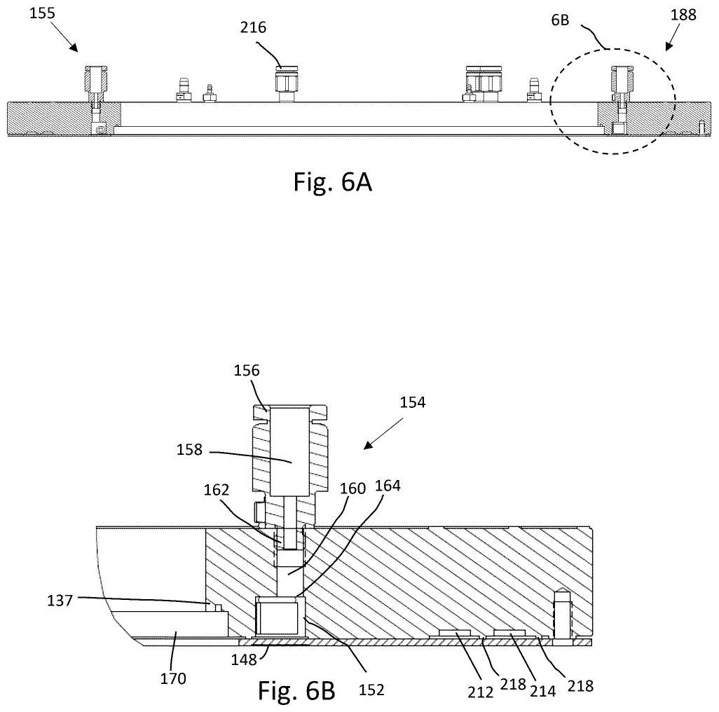

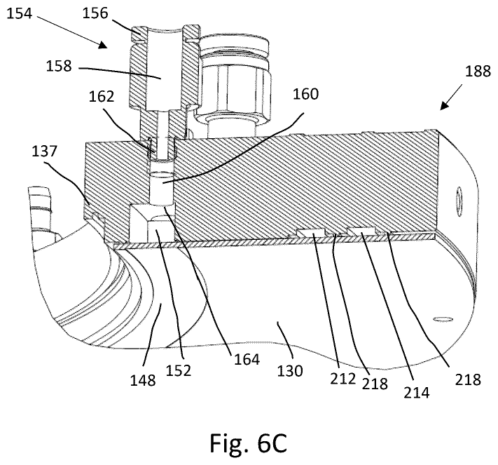

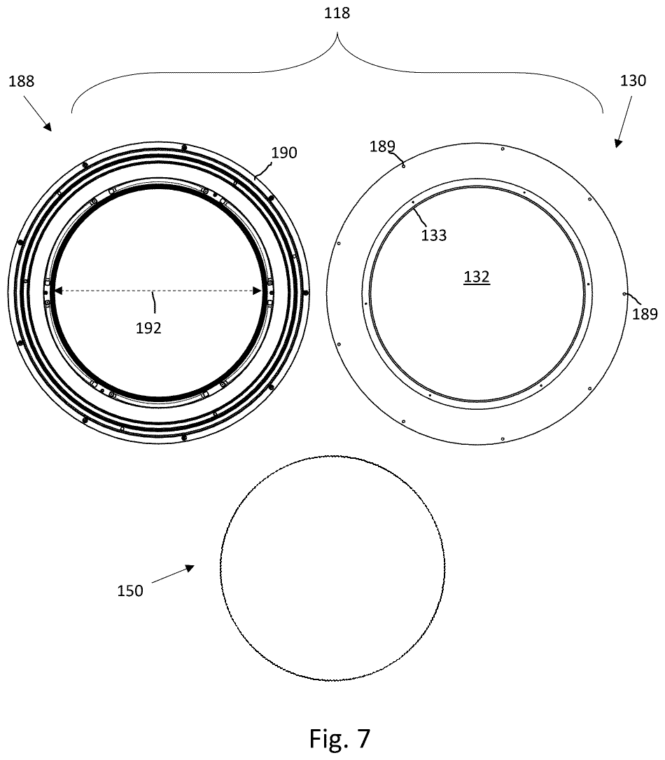

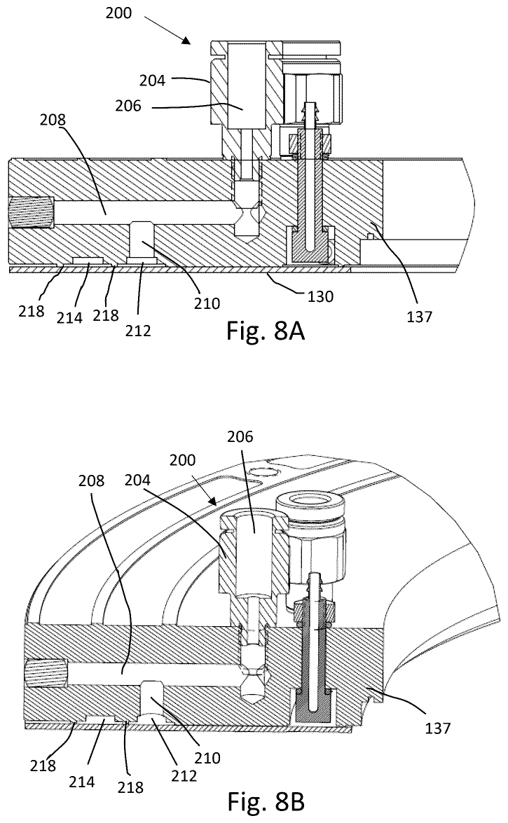

The fitting through hole 186 opens into the tube 166b. The tube 166b is best seen in FIGS. 5A to 5D. FIG. 5A is a cross-section view of the superstrate chuck assembly 118 taken along line 5A-5A of FIG. 3A. FIG. 5B is an enlarged view of portion 5B of FIG. 5A. FIG. 5C is a perspective view of portion 5B of FIG. 5A. FIG. 5D is an exploded perspective view of the superstrate chuck assembly 118. The second conduit 166 may include components that together allow the first channel 148 to impart a vacuum onto the superstrate 108. In the illustrated example embodiment, the second conduit 166 includes a port 168 connectable with a vacuum source (not shown). The port 168 may be connected to the vacuum source via a tube (not shown), for example. The tube 166b may be a flexible tube having a first end 180 connected to the bottom end of the fitting 166a and having a second end 182 connected to a second fitting attached to a channel through hole 187 formed through the plate holding member 130 and entering into the first channel 148. That is, by being connected to both the fitting 166a and the channel through hole 187, the tube 166b directs the vacuum suction downwardly into the first channel 148 via the channel through hole 187. Thus, when fitting 166a is connected to the vacuum source, a vacuum can be applied to first channel 148 to provide a suction force capable of coupling the area of the superstrate 108 under the first channel 148. Similarly, a positive pressure can be applied to the first channel 148 in the same manner.

One or more additional conduits may be implemented that have the same structure as the above-discussed second conduit 166, where each conduit is in communication with the same first channel 148 and/or communication with a corresponding additional channel (not shown) formed in the plate holding member 130. The additional channel or channels may be disposed concentrically around the first channel 148. That is, the additional channel or channels may also be concentrically disposed around the central opening 132, but may be located at a greater radial distance from the inner edge of the plate holding member 130 than the illustrated first channel 148. In an embodiment, the inner diameter of the plate holding member 130 may be smaller and/or the first channel 148 may have additional lands. As best seen in FIG. 4A, an additional conduit 167 having the same structure as the second conduit 166 may be located at a position diametrically opposing the second conduit 166. The additional conduits in communication with the first channel 148 assist in holding the superstrate fully to the plate holding member 130. In another aspect, additional channels corresponding to the first channel 148 at different concentric locations allow the same superstrate chuck assembly 118 to be used with different sized superstrates.

In another embodiment, it is possible that the first channel 148 and second conduit 166 may be replaced with another mechanism for coupling the plate holding member 130 with a superstrate. For example, in place of a channel/vacuum arrangement, an electrode that applies an electrostatic force may be included. Another option is mechanical latching where a mechanical structure on the underside of the plate holding member 130 is matable with the superstrate.

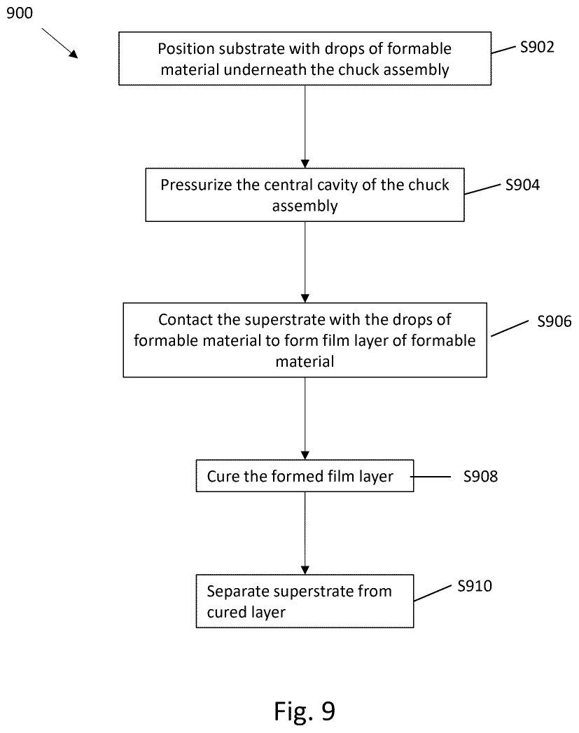

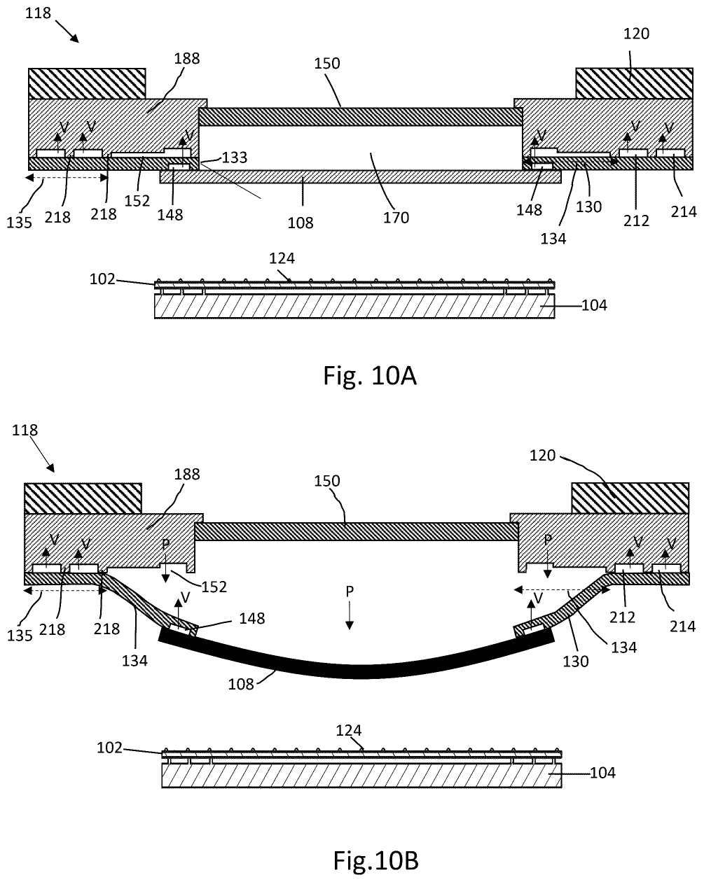

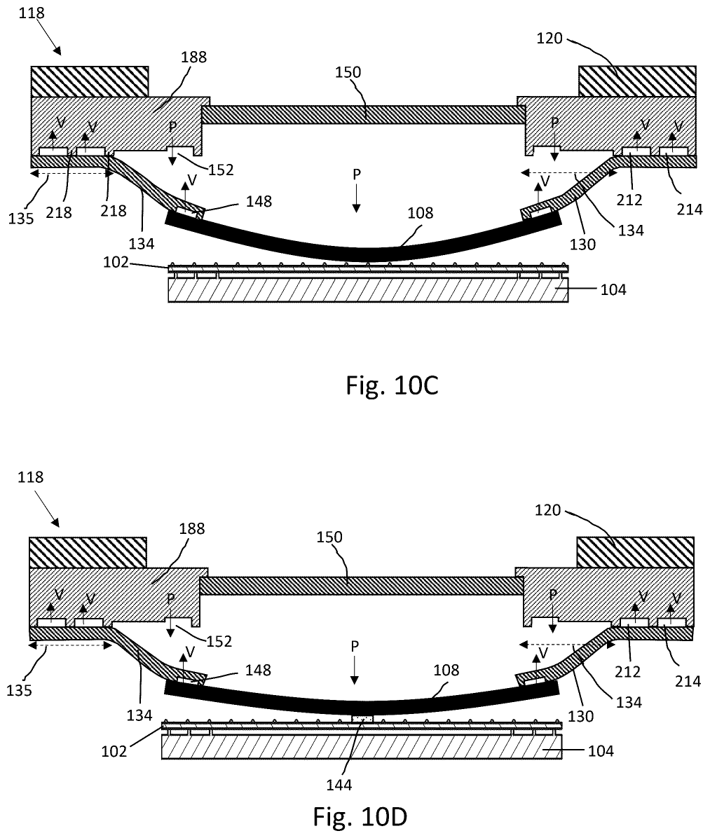

As noted above, the first fluid conduit 154 is in communication with the second channel 152 to pressurize the second channel 152 and to pressurize a cavity 170. The first fluid conduit 154 may include components that together allow the second channel 152 to be selectively positively or negatively pressurized. FIGS. 6A to 6C best show the first fluid conduit 154. FIG. 6A is a cross-section view of the superstrate chuck assembly 118 taken along line 6A-6A of FIG. 3B. FIG. 6B is an enlarged view of portion 6B of FIG. 6A. FIG. 6C is perspective view of the portion 6B of FIG. 6A. In the illustrated example, the first fluid conduit 154 includes a first port 156 connectable with a pressurizing source (not shown). The first port 156 may be connected to the pressurizing source via a tube (not shown), for example. The first port 156 includes a first cavity pressure control passage 158 in communication with a second cavity pressure control passage 160, where a first end 162 of the second cavity pressure control passage 160 connects with the first cavity pressure control passage 158 and a second end 164 of the second cavity pressure control passage 160 connects to the second channel 152. More specifically, the second end 164 may open into the first area 152a of the second channel 152. Thus, when the first port 156 is connected to the pressurizing source, positive pressure can be applied to pressurize the second channel 152 (including both the first area 152a and the second area 152b) via the first fluid conduit 154.

One or more additional fluid conduits may be implemented that have the same structure as the above-discussed first fluid conduit 154. For example, as best seen in FIG. 6A, an additional fluid conduit 155 having the same structure as the first fluid conduit 154 may be located at a position diametrically opposing the first fluid conduit 154. The one or more additional fluid conduits corresponding to the first fluid conduit 154 may serve the same function by opening into the second channel 152.

FIG. 7 shows an exploded view where the rigid member 188 is shown separated from the plate holding member 130 and the light transmitting member 150. As best seen in FIG. 7, the rigid member 188 may generally include a circular main body 190 defining an open central area 192. The outer circumference of the rigid member 188 may be uniform. The rigid member 188 holds the light transmitting member 150 such that the light receiving member 150 overlaps the open central area 192. The light transmitting member 150 may be secured to the rigid member 188 at the innermost step 137 with an adhesive, for example. In this manner, when the light transmitting member 150 is placed/secured to overlap the central area 192, a cavity 170 is defined by the underside surface of the light transmitting member, and the inner surface of rigid member 188. When a flexible portion of the plate holding member 130 below the second channel 152 extends away from the rigid member 188, the second channel 152 is in fluid communication with the cavity 170.

An edge of the plate holding member 130 may be coupled to the underside surface of the rigid member 188 using a coupling member such as a screw, nut/bolt, adhesive and the like. The coupling member may preferably be located adjacent the outer edge of the rigid member 188 and adjacent the outer edge of the plate holding member 130. When the coupling member is a screw, the coupling member preferably passes through the plate holding member 130 adjacent the outer edge of the plate holding member 130 and into the rigid member 188 adjacent the outer edge of the rigid member, such as through a plurality of receiving holes 189. When the coupling member is an adhesive, the coupling member is preferably located between the plate holding member 130 adjacent the outer edge of the plate holding member 130 and the rigid member 188 adjacent the outer edge of the rigid member. In this manner, an upper surface of the plate holding member 130 contacts and is fixed to the underside surface of the circular main body of the rigid member 188 adjacent the outer edge of the rigid member 188 and the outer edge of the plate holding member 130. Additional surface area of plate holding member 130 may be selectively coupled to the rigid member 188 as part of the planarization process. The manner of selectively coupling the additional surface area of the plate holding member 130 to the rigid member 188 is discussed in more detail below.

As shown in FIGS. 6A to 6C, a portion of the first conduit 154 and/or additional conduits serving the same function of the first conduit 154 may be contained within the rigid member 188, and as shown in FIGS. 4A to 5C, a portion of the second conduit 166 and/or additional conduits serving the same function of the second conduit 166 may be contained within the rigid member 188. More particularly, a portion of the fitting 166a and a portion of the tube 166b is located within the rigid member 188. Significantly, the second channel 152, within the rigid member 188, provides two functions. First, the second channel 152 retains a portion of the fitting 166a and a portion of the tube 166b. Second, the first conduit 154 opens into the second channel 152 in order to control the pressure in the second channel 152 to extend or retract the plate holding member 130. Thus, the second channel 152 functions to retain certain structure and also acts as a pressure control space to act upon the plate holding member 130.

The superstrate chuck assembly 118 may further include additional fluid conduits in communication with additional channels that serve the function of selectively securing portions of the plate holding member 130 to the underside surface of the rigid member 188. While the above-described fluid conduits communicate with the first channel 148 of the plate holding member 130 or communicate with the second channel 152, the fluid conduits that selectively secure portions of the plate holding member 130 to the underside surface of the rigid member 188 communicate with additional annular cavities in the rigid member 188 that are open on the underside surface of the rigid member 188.

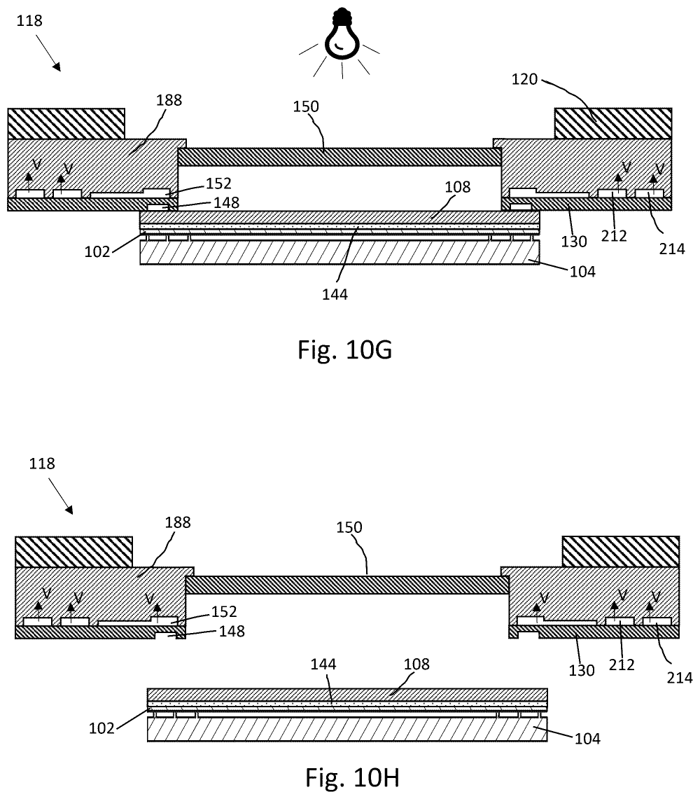

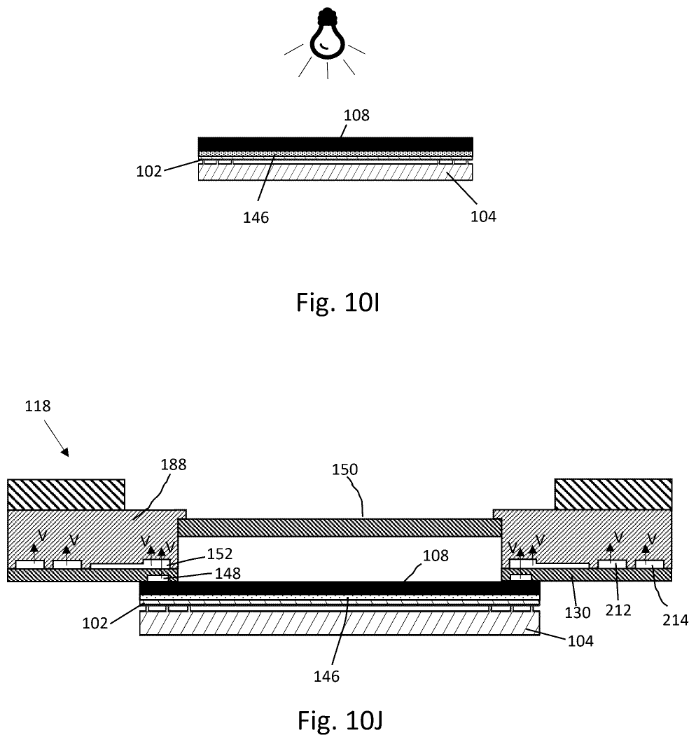

FIGS. 8A and 8B show an example of a third fluid conduit 200 used for selectively securing the plate holding member 130 to the rigid member 188. FIG. 8A shows an enlarged portion 8A of FIG. 4A. FIG. 8B shows a side perspective view of the enlarged portion 8A of FIG. 4A. The third fluid conduit 200 may include components that together impart a vacuum suction force onto the upper surface of the plate holding member 130 to further secure the plate holding member 130 to the underside surface of the rigid member 188. In the illustrated example embodiment, the third fluid conduit 200 includes a first port 204 connectable with a vacuum source (not shown). The first port 204 of the third fluid conduit 200 may be connected to the vacuum source via a tube (not shown), for example. As best seen in FIGS. 8A and 8B, the third fluid conduit 200 includes a first member holding vacuum passage 206 connected with a second member holding vacuum passage 208, and the second member holding vacuum passage 208 is connected with a third member holding vacuum passage 210. As also best seen in FIGS. 8A and 8B, the first member holding vacuum passage 206 may be oriented vertically to direct the vacuum downwardly, the second member holding vacuum passage 208 of the third fluid conduit 200 may be oriented horizontally to direct the vacuum radially, and the third member holding vacuum passage 210 of the third fluid conduit 200 may be oriented vertically to direct the vacuum downwardly. The third member holding vacuum passage 210 of the third fluid conduit 200 may be connected a third channel 212 having an open end facing downwardly toward the plate holding member 130. Thus, when the first port 204 of the third fluid conduit 200 is connected to the vacuum source, and the upper side surface of the plate holding member 130 is in contact with the underside surface of the rigid member 188, a vacuum can be applied to the third channel 212 of the rigid member 188 to secure the plate holding member 130 to the rigid member 188, via the third fluid conduit 200. The third channel 212 may be an annular channel located radially outward of the second channel 152.

The same principle of the third fluid conduit 200 to control the pressure in the third channel 212 can be applied to additional channels in the rigid member 188. For example, as shown in FIGS. 4B, 4C, 5B, 5C, 6B, 6C, 8A, 8B, a fourth channel 214 may be present in in the rigid member 188. The fourth channel 214 is also an annular channel and is located radially outward of the third channel 212. A corresponding fourth fluid conduit 216 is included which has the same structure and function as the third fluid conduit 200. The difference between the fourth fluid conduit 216 and the third fluid conduit 200 is only that it provides fluid communication between a vacuum source and the fourth channel 214. Because each of the channels are at different radial locations, each channel will apply a suction force to a different annular section of the upper side surface of the plate holding member 130. Furthermore, because each of the channels are in communication with a vacuum source via distinct flow paths, the vacuum can be independently applied to each channel. For example, if a vacuum is applied only to the third channel 212, then the suction force will only be imparted on the portion of upper side surface of the plate holding member 130 that contacts the third channel 212. However, if vacuum is applied to both the third channel 212 and the fourth channel 214 at the same time, then suction force will be imparted on the a wider area of the upper side surface of the plate holding member 130, i.e., the portion of the upper side surface of the plate holding member 130 that contacts the third channel 212 and the portion of the upper side surface of the plate holding member 130 that contacts the fourth channel 214.

While the illustrated example embodiment shows two channels in addition to the second channel 152, further channels and further corresponding fluid conduits can be included to provide finer control of how much of the member is suctioned against the rigid member 188 at a particular time in the planarization process. The number of additional channels may be chosen to provide the optimal control over how much surface area of the plate holding member 130 is suctioned underneath the rigid member 188. For example, the number of channels may be from 1 to 10, from 3 to 7, or from 4 to 6. The channels may be of varying size. The ratio of the cross sectional area of one of the channels to the cross sectional area of another one of the channels may be from 10:1 to 1:1, from 8:1 to 4:1, or from 5:1 to 3:1. Some of the channels may have the same size and shape. The channels may have a cross section shape that is rectangular or square. The rigid member 188 may further include lands 218 between adjacent annular cavities. The lands 218 are the portion of the rigid member 188 that comes into contact with the upper surface of the plate holding member 130.

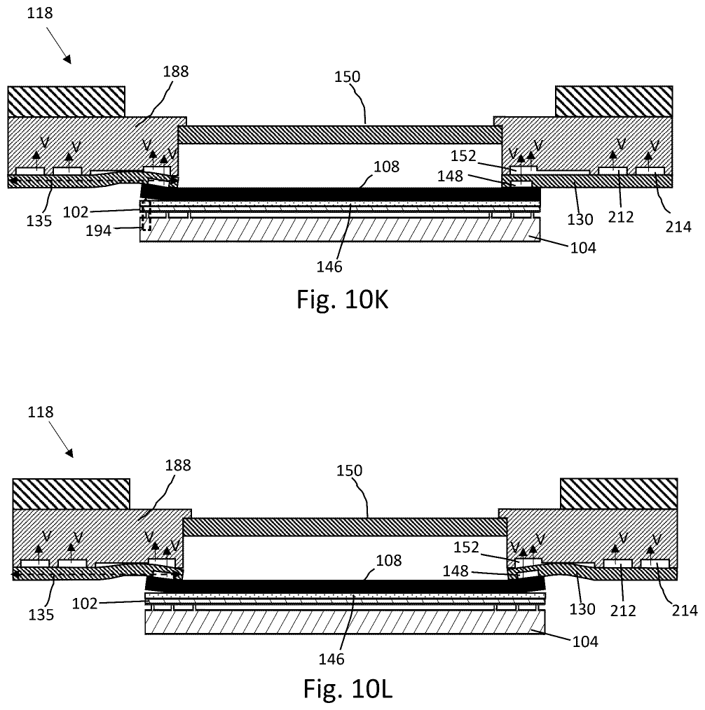

Operation of the superstrate chuck assembly 118 as part of the planarization process will now be described with reference to FIGS. 9 and 10A to 10N. FIG. 9 shows a flow chart of a planarization method 900. The method begins at step S902, where the substrate 102 having drops of formable material 124 dispensed thereon, is brought underneath the superstrate 108 that is coupled with the plate holding member 130 of the superstrate chuck assembly 118. Thus, prior to performing step S902, the drops of formable material are dispensed onto the substrate in the manner described above. This state of step S902 is shown in FIG. 10A, which is a schematic cross section of the superstrate chuck assembly 118.

Additionally, prior to forming step S902, the superstrate chuck assembly 118 is prepared by applying the vacuum suction to the first channel 148 of the plate holding member 130 and contacting the first channel 148 to the upper side surface of the superstrate 108, thereby coupling the superstrate 108 to the plate holding member 130. In a case where there are multiple vacuum channels (e.g., 2) in the flexible portion 134 of the plate holding member 130, in one embodiment, less than all (e.g., only one) of the vacuum channels will have a vacuum implemented during step S902. For example, in one embodiment, only the radially outermost first channel relative to the central opening 132 may have a vacuum imparted. However, in another embodiment, all the vacuum channels (e.g., 2) may have a vacuum implemented during step S902.

FIGS. 10A through 10N show schematic cross section view of the chuck assembly throughout the planarizing process, from forming a film layer, to curing the layer, through separation of the superstrate from a cured layer. As shown in FIG. 10A, at the time that the substrate 102 is placed underneath the superstrate 108, the cavity 170 is not yet pressurized with positive pressure. At the moment shown in FIG. 10A, the pressure P in the second channel and the cavity are preferably equal to atmospheric pressure. Furthermore, either prior to positioning the substrate 102 under the superstrate 108 or prior to step S904, the vacuum suction V may be applied to all of the channels 212, 214, 152. The vacuum imparted to the channels 212, 214 may be strong enough to couple the plate holding member 130 to the rigid member such that the portion of the member is effectively rigid, i.e., creating a rigid portion 135. However, the vacuum applied to the second channel 152 may be selected such that, while the inner edge 133 of the member contacts the rigid member 188, the vacuum is not strong enough to pull the plate holding member 130 into the second channel 152. This causes the portion of the plate holding member 130 beneath the second channel 152 to be effectively flexible, i.e., creating a flexible portion 134.

The method may proceed to step S904, where the cavity 170 of the superstrate chuck assembly 118 is pressurized with positive pressure. FIG. 10B shows a schematic cross section of the superstrate chuck assembly 118 after the cavity 170 has been pressurized. The cavity 170 may be pressurized by imparting a positive pressure P via the second channel 152 and the first fluid conduit 154. The amount of pressure P may be selected such that it is sufficient to bow the superstrate 108 with a desired curvature, as shown in FIG. 10B. The pressure P may be set to 0.1 to 10 kPa. At the same time, the vacuum suction is applied to the first channel 148, the channel third channel 212, and the fourth channel 214. Thus, during step S904, the plate holding member 130 remains attached to the superstrate 108 via the first channel 148 and the plate holding member 130 remains attached to the rigid member 188 at the areas below the third channel 212 and the fourth channel 214. As noted above, the portion of the plate holding member 130 that is suctioned to contact the underside of the rigid member 188 is effectively the rigid portion 135, while the portion of the plate holding member 130 not suctioned against the underside of the rigid member 188 is effectively the flexible portion 134. In the present context, effectively rigid means that a portion of the plate holding member that is secured to the rigid member is prevented from deflecting by more than a deflection threshold (the deflection threshold may be 0.1-10 μm depending on the planarization system) in the z direction towards or away from the rigid member by the forces that are available in the planarization system. The portion that is effectively rigid may be in a deflected stated by more than the deflection threshold while it is secured to the rigid member. In the present context, effectively flexible means that a portion of the plate holding member can be deflected by more than the deflection threshold in the z direction towards and away from the rigid member and towards the substrate chuck by the forces available in the planarization system. As also shown in FIG. 10B, because the positive pressure P, and the bowing of the superstrate 108, the flexible portion 134 of the plate holding member 130 will bend/bow as well, while the rigid portion 135 does not bend. The second channel 152 may be positively pressurized to pressure P prior to moving the superstrate chuck assembly 118 toward the substrate 102 or as the superstrate chuck assembly 118 moves toward the substrate 102. In the case that the pressurizing occurs while the superstrate chuck assembly 118 moves toward the substrate 102, the target pressure should be reached prior to the superstrate 108 coming into contact with the formable material 124.

The method may proceed to step S906, where the superstrate 108 is brought into contact with the drops of formable material 124 on the substrate 102 to form a film layer 144. FIG. 10C shows a schematic cross section of the superstrate chuck assembly 118 just before the bowed superstrate 108 comes into contact with the drops of formable material 124. As shown in FIG. 10C, the positive pressure P is still maintained in the second channel 152 and the cavity 170, while and the vacuum suction is still applied to the first channel 148, the third channel 212, and the fourth channel 214. In an embodiment, the pressure P in the second channel 152 and cavity 170 is increased as the superstrate 108 conforms with the formable material 124 to maintain a desired curvature. It often requires more pressure to maintain a certain superstrate curvature as the un-conformed region of the superstrate decreases. As a contact area of the superstrate increases during step S906 the contact area of the superstrate begins to conform to the shape of the superstrate under the contact area, while the portion of the superstrate outside the contact area is the un-conformed region in which the curvature needs to be controlled. Maintaining this curvature is important for minimizing gas trapping which can lead to non-fill defects. In an embodiment, the curvature just beyond the conformed portion (contact area) of the superstrate is controlled. In other words, the curvature of the superstrate in an annular region just outside the contact area is controlled. In an embodiment, a desired superstrate curvature profile in this annular region is controlled while formable material spreads underneath the contact area. This may require that the pressure P be maintained and/or increased during step S906. In an embodiment, the superstrate 108 is ‘flat’ (conforms to the shape of the substrate 102) after the formable material has stopped spreading.

FIG. 10D shows a schematic cross section of the superstrate chuck assembly 118 as it continues to move downwardly toward the substrate 102 to form the film 144. As shown in FIG. 10D, as the superstrate chuck assembly 118 continues to move the superstrate 108 downwardly, a film 144 of the formable material 124 begins to form in an area between the center of the superstrate 108 and the substrate 102. Simultaneously with this action, the positive pressure P in the second channel 152 and the cavity 170 may be maintained or increased so that as the superstrate 108 is pressed against the formable material 124, the superstrate 108 will maintain the desired curvature in the area of the superstrate that is about to conform with the formable material. Preferably, the pressure P is increased. That is, as seen in FIG. 10D as compared to FIG. 10C, the superstrate 108 has less of an arc in FIG. 10D such that the area of the superstrate that is about to conform with the formable material maintains the desired curvature. At the same time the flexible portion 134 of the plate holding member 130 may begin to flatten along with the superstrate 108.

FIG. 10E shows a schematic cross section of the superstrate chuck assembly 118 at a point where the superstrate 108 is has been further pushed toward the substrate 102. As seen in FIG. 10E, as the superstrate 108 continues to press downwardly, the film 144 of formable material 124 spreads further along the surface of the substrate 102 toward the edges. The positive pressure P is further increased or maintained in the second channel 152 and the cavity 170 so as to maintain the desired curvature in the area of the substrate that is about to conform with the formable material. Preferably, the pressure P is further increased. Thus, as the superstrate 108 continues to press downwardly toward the substrate 102, the superstrate 108 continues to bend to maintain the desired curvature in the area of the substrate that is about to conform with the formable material. That is, the superstrate 108 in FIG. 10E has less of an arc than in FIG. 10D such that the area of the superstrate that is about to conform with the formable material maintains the desired curvature. At the same time, the flexible portion 134 also continues to flatten relative to FIGS. 10C and 10D. That is, the flexible portion 134 is flatter in FIG. 10E than in FIG. 10D. The vacuum suction is still applied to the first channel 148, the third channel 212, and the fourth channel 214, throughout the positions shown in FIGS. 10D and 10E.

FIG. 10F shows a schematic cross section of the superstrate chuck assembly 118 at a point where the superstrate 108 has been fully pressed against the formable material 124 such that the film 144 is fully formed. As shown in FIG. 10F, the superstrate 108 has been pressed until it is once again flat. That is, the superstrate 108 no longer has an arc or lacks a substantial arc. Similar, the flexible portion 134 of the plate holding member 130 is flat or lacks a substantial bend. At this stage there may be a small gap between an innermost land of the rigid member 188 and the plate holding member 130 such that there is a fluid connection between the cavity 170 and the second channel. The positive pressure in the second channel 152 and the cavity 170 at this point is completely removed or open to atmosphere. The vacuum suction is still applied to the first channel 148, the third channel 212, and the fourth channel 214, as the moment shown in FIG. 10E is prior to curing and prior to the release process described below. As the forming of the film 144 is reaching completion, there may be a minor amount of positive pressure in the second channel 152 to counteract any minor amount of upward force on the portion of the plate holding member 130 below the second channel 152 caused by the pressing of the superstrate 108 against the formable film 144. The minor amount of positive pressure at this moment would be just enough to counteract the upward force. Once the film 144 is completely formed and there is no longer any force pressing the superstrate 108 against the formable material film 144, the pressure in the second channel 152 can be atmospheric without any positive or negative pressure applied.

As a result of the flexible portion 134 of the plate holding member 130 being coupled with the superstrate 108, the above-described difficulty in controlling the superstrate curvature and spread of polymerizable material near the edge of the superstrate is reduced or avoided as compared to a chuck assembly lacking the flexible portion. This is because the flexible portion 134 of the plate holding member 130 has less bending stiffness than the superstrate 108 and bends with the superstrate 108 during spreading of the formable material 124. Thus, by controlling the pressure in the second channel 152 and the cavity 170, the flexible portion 134 is provided, and the curvature of superstrate 108 can be controlled throughout the spreading process from the center to the outer edge of the superstrate 108. In addition to this feature of controlling the curvature of the superstrate as described above, the superstrate chuck assembly 118 also can provide consistent crack propagation during the time of separating the superstrate from the cured material. The separation aspect of the superstrate chuck assembly 118 begins with the description of FIG. 10J.

The method may then proceed to step S908, where the formed film 144 located between the superstrate 108 and the substrate 102 is cured. FIG. 10G shows a schematic cross section of the superstrate chuck assembly 118 during the curing step of step S908 in accordance with a first example embodiment. In the first example embodiment, the curing step may be performed in the manner noted above using the curing system. The radiation source 126 may emit, for example, UV radiation that is directed through the light-transmitting member and through the superstrate 108, each of which allow the UV radiation to pass through. In an embodiment the plate holding member 130 may be transparent to the UV radiation so that the member will not interfere with the curing process. In an embodiment the rigid member 188 may be transparent to the UV radiation so that the member will not interfere with the curing process. In another embodiment the plate holding member 130 need not be transparent with respect to UV radiation. In a case that the plate holding member 130 is opaque with respect to UV radiation, the plate holding member 130 will need to be moved relative to a multilayer structure (substrate 102; uncured formable material film 144; and superstrate 108) while the uncured formable material film 144 in the multilayer combination is being cured during step S908. In this first example embodiment, where the UV radiation passes through the light-transmitting member, the light-transmitting member 150 may be composed of a material that transmits greater than 80% of light having a wavelength of 310-700 nm (i.e., UV light and visible light), e.g., sapphire, fused silica). After exposure to the UV radiation, the film 144 of formable material is cured, thereby forming a hardened cured layer 146. In an embodiment, during the curing process the vacuum suction is not applied to the first channel 148.

FIGS. 10H and 101 show a schematic cross section of the superstrate chuck assembly 118 during the curing step of step S908 in accordance with a second example embodiment. In the second example embodiment, as shown in FIG. 10H, the superstrate 108 is first released from the plate holding member 130. Thus, at this moment the vacuum applied to the first channel 148 has been terminated. After the superstrate 108 has been released from the plate holding member 130, the multilayer structure (combination of superstrate 108/film 144/substrate 102/substrate chuck 104) may be moved via the stage to another location. As shown in FIG. 10I, once the multilayer structure is present at the other location, the curing process can be performed. As in the first embodiment, the curing may be performed by exposing the film 144 to UV light through the superstrate 108. However, because the multilayer structure is at another location and no longer coupled to the superstrate chuck assembly 118, the UV light does not need to pass through the light-transmitting member 150 or through the plate holding member 130. In this second example embodiment, where the UV radiation does not pass through the light-transmitting member, the light-transmitting member 150 may be composed of a material that transmits greater than 80% of light having a wavelength of 400-700 nm (i.e., visible light and not UV light), e.g., glass, borosilicate, and does not need to be composed of a material that transmits UV light. After the curing is complete, the multilayer structure may be brought back to the superstrate chuck assembly 118 and the superstrate 108 may be once again coupled with the plate holding member 130 by providing a vacuum to the first channel 148.

The method may then proceed to step S910, where the superstrate 108 is separated from the cured layer 146. In the case of the embodiment shown in FIG. 10G, the superstrate 108 has never been decoupled from the superstrate chuck assembly 118 and is therefore already positioned for separation. In the case of the embodiment shown in FIGS. 10H and 101, after the curing is complete, as noted above, the superstrate 108 has once again been coupled with the superstrate chuck assembly 118 and is ready for separation.

The separating of the superstrate 108 from the cured layer 146 may be performed by lifting the superstrate chuck assembly 118 upwardly away from the substrate 102 along with propagating a separation front between the superstrate 108 and the cured layer 146. The process of initiating the separation front may be performed prior to beginning to lift the superstrate chuck assembly 118. Just prior to beginning the process of initiating the separation front, the vacuum suction applied to the third channel 212 and the fourth channel is 214 is maintained. Additionally, a vacuum is also applied to the second channel 152. FIG. 10J shows the superstrate chuck assembly 118 just prior to initiating the separation front in an example embodiment where a vacuum is applied to first channel 148, the second channel 152, the third channel 212, and the fourth channel 214. That is, as shown in FIG. 10J, even with vacuum force applied to the second channel 152, the portion of the plate holding member 130 below the second channel 152 is substantially flat and not pulled into the space of the second channel 152. At the same time, the superstrate 108 is fully contacting the cured layer 146. Thus, at the moment shown in FIG. 10J, there has not yet been any separation of the superstrate 108 from the cured layer 146, i.e., the separation front has not yet been initiated.

FIG. 10K shows the superstrate chuck assembly 118, at the point of initiating a separation front between the superstrate 108 and the cured layer 146. This separation front may be initiated by raising a pin 194 that passes through an orientation feature of the substrate until it comes into contact with and pushes upwardly against the underside of the superstrate 108. At the same time, the vacuum in the second channel 152 is maintained. As shown in FIG. 10K, once the pin 194 pushes up against the superstrate 108 to initiate the separation front, the superstrate 108 lifts from the cured layer 146, thereby also freeing the portion of the plate holding member 130 below the second channel 152. Because the vacuum is maintained in the second channel 152, and because the plate holding member 130 is flexible, the portion of the plate holding member 130 under the second channel 152 is suctioned upwardly until the upper side of the plate holding member 130 contacts the second surface 153e of the second channel 152. Once the plate holding member 130 contacts the second surface 153e of the second channel 152, the portion of the plate holding member 130 under the second channel 152 is effectively rigid. In other words, because of the vacuum force holding the portion of the plate holding member 130 against the second surface 153e, the plate holding member 130 no longer can serve a flexible function. Initially only a small arc segment of upper side of the flexible portion opposite the pin is close to or in contact with the second surface 153e. After this initial state and vacuum is supplied to the second channel 152, larger portions of the upper side of the flexible portion come into contact with the second surface helping the separation front propagate around the circumference of substrate 102. The flexible portion of plate holding member 130 is deflected in a specific manner which assists in propagating the separation front that would be lacking if the plate holding member 130 were not limited their deflection.

FIG. 10L shows the superstrate chuck assembly 118 after the separation front initiated in FIG. 10K has propagated around the circumference of the substrate 102. As the vacuum is maintained in the second channel 152, optionally along with some lifting and/or tilting of the superstrate chuck assembly 118 the separation front between the superstrate 108 and the cured layer 146 continues to propagate. The propagation first occurs circumferentially. Thus, as shown in FIG. 10K, the separation between the superstrate 108 and the cured layer 146 has reached the opposite side of pin side in FIG. 10K, but there has been little separation in the radial direction toward the center of the substrate 102. As explained above, as the edges of the superstrate 108 lift from the cured layer 146, the corresponding portion of the plate holding member 130 lifts as a result of the vacuum and comes into contact with the second surface 153e, thereby limiting the ability of the flexible portion to be deflected beyond a specific amount. As noted above with respect to FIG. 4D, the second surface 153e is at the distance H3 relative to the bottom of the sidewalls 153a, 153d. The distance H3 is selected such that there is enough distance for the plate holding member 130 to lift to allow for the separation front to propagate along the circumference, while also limiting the amount of deflection of the plate holding member 130. In other words, the distance H3 is particularly chosen so the portion of the plate holding member 130 under the second channel 152 has enough room to lift as part of propagating the separation front along the circumference, but the distance H3 also provides a backstop so that the plate holding member 130 and the first channel are held at a specific distance from the substrate and at a specific orientation that aids with the propagation of the separation front from the pin to around the substrate.

FIG. 10M shows a moment after FIG. 10L after further separation of the superstrate 108 from the cured layer 146. In FIG. 10M, the superstrate chuck assembly 118 has been lifted upwardly to propagate the separating from in a radial direction toward the center of the superstrate 108. As shown in FIG. 10M, because the portion of the plate holding member 130 below the second channel 152 is secured to the second surface by vacuum there is no additional deflection of the flexible portion. That is, the superstrate chuck assembly 118 can be continued to be lifted to propagate the separation of the superstrate 108 from the cured layer 146 without the plate holding member 130 flexing. In an embodiment, after the separation front has propagated around the circumference of the substrate 102, the vacuum in the second channel 152 may be reduced. The flexible portion 134 of the plate holding member 130 being secured against the second surface 153e ensures that the first channel 148 which holds the plate holding member 130 is at the desired position and orientation to ensure that the propagation of the separation front around the circumference of the substrate succeeds.

FIG. 10N shows a moment once the separation of step S910 has been completed just after superstrate 108 has been released from the cured layer 146. As shown in FIG. 10N after completing the separation, the superstrate chuck assembly 118 retains the superstrate 108 and the substrate 102 retains the cured layer 146. The planarization process 900 can then be started again for another substrate by returning to the orientation shown in FIG. 10A. As noted above, the planarization process 900 may be repeated many times, on the order of tens of thousands. When it is desirable to remove the superstrate 108 from the superstrate chuck assembly 118 (for example after a predetermined number of planarization processes have been completed or if some other indicator suggests that the superstrate should be replaced), the vacuum applied to the first channel 148 may be released.

Further modifications and alternative embodiments of various aspects will be apparent to those skilled in the art in view of this description. Accordingly, this description is to be construed as illustrative only. It is to be understood that the forms shown and described herein are to be taken as examples of embodiments. Elements and materials may be substituted for those illustrated and described herein, parts and processes may be reversed, and certain features may be utilized independently, all as would be apparent to one skilled in the art after having the benefit of this description.

What is claimed is:

1. A chuck assembly for holding a plate, comprising:
a plate holding member configured to hold the plate, the plate holding member including a central opening;
a rigid member configured to hold the plate holding member;
a first channel formed by the plate holding member;
a second channel formed by the rigid member;
a first fluid conduit in communication with the second channel; and
a second fluid conduit at least partially disposed within the second channel and in communication with the first channel.

2. The chuck assembly of claim 1, wherein the plate is held by the plate holding member by reducing pressure in the first channel via the second fluid conduit.

3. The chuck assembly of claim 1, wherein the plate holding member is composed of a flexible material.

4. The chuck assembly of claim 1, wherein a portion of the plate holding member is movable by adjusting pressure in the second channel via the first fluid conduit.

5. The chuck assembly of claim 4, wherein the second channel overlaps the portion of the plate holding member.

6. The chuck assembly of claim 1, further comprising:
a third fluid conduit,
wherein the rigid member comprises a third channel facing the plate holding member, and
wherein the third fluid conduit is in communication with the third channel.

7. The chuck assembly of claim 1, wherein the first fluid conduit has a first end opening into the second channel and a second end coupled with a pressure source.

8. The chuck assembly of claim 1, wherein the second channel overlaps the first channel.

9. The chuck assembly of claim 1, wherein the second fluid conduit has a first end opening into the first channel and a second end coupled with a pressure source.

10. The chuck assembly of claim 9,
wherein the second fluid conduit includes a fixture and a tube extending from the fixture,
wherein the tube comprises the first end opening into the first channel, and
wherein the fixture comprises the second end coupled with the pressure source.

11. The chuck assembly of claim 10, wherein a portion of the fixture is positioned within the second channel.

12. The chuck assembly of claim 11, wherein the portion of the fixture positioned within the second channel does not extend beyond a bottom surface of the rigid member.

13. The chuck assembly of claim 10, wherein a portion of the tube is positioned within the second channel.

14. The chuck assembly of claim 10, further comprising sealing members coupled with the fixture.

15. The chuck assembly of claim 1,
wherein the second channel is partly defined by a first sidewall extending from a first surface of the rigid member and a second sidewall extending from the first surface of the rigid member, and
wherein the first sidewall extends farther from the first surface than the second sidewall.

16. The chuck assembly of claim 15, wherein the first sidewall is located radially inward of the second sidewall.

17. The chuck assembly of claim 16,
wherein the first channel is partly defined by a third sidewall extending from the first surface of the plate holding member, and
wherein the first sidewall overlaps the third sidewall.

18. The chuck assembly of claim 15, wherein the first sidewall extends 5 to 100 μm beyond the second sidewall.

19. A planarization system, comprising:
a chuck assembly for holding a plate, the chuck assembly comprising:
a plate holding member configured to hold the plate, the plate holding member including a central opening;
a rigid member configured to hold the plate holding member;
a first channel formed by the plate holding member;
a second channel formed by the rigid member;
a first fluid conduit in communication with the second channel; and
a second fluid conduit at least partially disposed within the second channel and in communication with the first channel;
a substrate chuck configured to hold a substrate;
a fluid dispenser configured to dispense formable material on the substrate;
a positioning system configured to contact the formable material with the plate; and
a curing system configured to cure the formable material under the plate so as to form cured formable material on the substrate.

20. A method of manufacturing an article, comprising:
dispensing a formable material on a substrate;
retaining a plate with a plate chuck assembly, the plate chuck assembly comprising:
a plate holding member configured to hold the plate, the plate holding member including a central opening;
a rigid member configured to hold the plate holding member;
a first channel formed by the plate holding member;
a second channel formed by the rigid member;
a first fluid conduit in communication with the second channel; and
a second fluid conduit at least partially disposed within the second channel and in communication with the first channel;
contacting the plate with the formable material dispensed on the substrate;
curing the formable material with a curing source;
separating the plate from the cured formable material; and
processing the cured formable material to make the article.
